(19) United States
(12) Patent Application Publication
(10) Pub. No.: US 2026/0305246 A1
(43) Pub. Date: Oct. 1, 2026

(54) APPARATUS, SYSTEM AND METHOD FOR ALIGNING FLAT PANELS AND FILM FRAMES

(71) Applicant: JABIL INC., St. Petersburg, FL (US)

(72) Inventor: JEROEN BOSBOOM, St. Petersburg, FL (US)

(21) Appl. No.: 19/481,212

(22) PCT Filed: May 1, 2024
(86) PCT No.: PCT/US2024/027161

§ 371 Date: Nov. 4, 2025

Related U.S. Application Data
(60) Provisional application No. 63/465,305, filed on May 10, 2023.

(51) Int. Cl. H10P 72/50

(52) U.S. Cl. CPC H10P 72/50

(57) ABSTRACT

An apparatus, system and method for providing a flat element aligner. Included in the embodiments are: an aligner body; two opposing slides which are along at least first parallel axes to each other, each of which terminates in a side guide distally from a center point of the aligner body, and each of which slides along a slot in an upper portion of the aligner body; two opposing justifiers which are along at least second parallel axes to each other and which are perpendicular to the two opposing slides, each of which terminates in a roller distally from the center point of the aligner body, and each of which slides along a slot in the upper portion of the aligner body; and at least one drive within the aligner body and below the upper portion that synchronously and symmetrically moves at least the two opposing slides closer together and farther apart, and that synchronously and symmetrically moves at least the two opposing justifiers closer together and farther apart, such that the opposing side guides and opposing rollers.

### CROSS-REFERENCE TO RELATED APPLICATIONS

The present application claims the benefit of priority to U.S. Provisional Application No. 63/465,305, filed May 10, 2023, entitled “Apparatus, System and Method for Aligning Flat Panels and Film Frames,” the contents of which are incorporated by reference herein in their entirety.

### FIELD OF THE INVENTION

The disclosure relates generally to manufacturing, and, more particularly, to an apparatus, system, and method for aligning flat panels and film frames.

### BACKGROUND

The production of microchips involves separating the hundreds of discrete chips from the silicon wafer on which they were printed. The wafers are commonly placed in a circular film frame containing a stretched plastic liner with an adhesive glue film. The film frame is configured as a 1-2 mm thick stainless-steel rim with a clearance hole for the wafer, and with squared off edges and locating slots on one edge.

This film frame and wafer assembly is then carried through the process of sawing the individual chips in subsequent manufacturing steps. Such steps may comprise, for example, retrieving the finished chips for placement with robotics.

Further, the automated handling of film frames (FF) requires alignment stages each time that the FF is moved along in the process. Film frames are often stored in FF cassettes and retrieved robotically for other tools. Critical registration for alignment is often compromised between storage and actual work events. It's therefore necessary to justify and locate the FF or flat panel (FP or FPD) when retrieving it from storage.

It is standard practice to use registration v-notches to repeatably register a FF so that the subsequent placements are repeatable. For instance, the chip yield is diminished if the wafer alignment is mis-indexed by not registering the FF beforehand.

Currently there are no tools that can accommodate a wide variety of substrate sizes, given the need for registration and alignment. With the advent of a multitude of wafer and FF sizes, tools designed to handle multiple FF sizes would be very useful to efficiently process different size FF batches in one work cell.

Therefore, the need exists for a flat element aligner to reduce overall cost by leveraging flexibility and a small footprint compared to the current dedicated FF alignment stages that typically handle only one size. Of additional note, the multiple sizes of substrates shown herein are nonlimiting, and thus the sizes detailed in the disclosure may be scaled up or down, for width or length, for the purposes of the discussion herein.

### SUMMARY OF THE DISCLOSURE

The embodiments provide an apparatus, system and method for providing a flat element aligner. Included in the embodiments are: an aligner body; two opposing slides which are along at least first parallel axes to each other, each of which terminates in a side guide distally from a center point of the aligner body, and each of which slides along a slot in an upper portion of the aligner body; two opposing justifiers which are along at least second parallel axes to each other and which are perpendicular to the two opposing slides, each of which terminates in a roller distally from the center point of the aligner body, and each of which slides along a slot in the upper portion of the aligner body; and at least one drive within the aligner body and below the upper portion that synchronously and symmetrically moves at least the two opposing slides closer together and farther apart, and that synchronously and symmetrically moves at least the two opposing justifiers closer together and farther apart, such that the opposing side guides and opposing rollers.

Thus, in satisfaction of the aforementioned need, the embodiments provide a method, system and apparatus for a flat element aligner that reduces overall cost by leveraging flexibility and a small footprint compared to the current dedicated FF alignment stages that typically handle only one size.

### BRIEF DESCRIPTION OF THE DRAWINGS

This disclosure is illustrated by way of example and not by way of limitation in the accompanying figure(s). The figure(s) may, alone or in combination, illustrate one or more embodiments of the disclosure. Elements illustrated in the figure(s) are not necessarily drawn to scale. Reference labels may or may not be repeated among the figures to indicate corresponding or analogous elements.

FIG. 1 illustrates aspects of an exemplary embodiment of the present invention;

FIG. 2 illustrates aspects of an exemplary embodiment of the present invention;

FIG. 3 illustrates aspects of the embodiments;

FIG. 4 illustrates aspects of the embodiments;

FIG. 5 illustrates aspects of an exemplary embodiment of the present invention;

FIG. 6 illustrates aspects of an exemplary embodiment of the present invention;

FIG. 7 illustrates aspects of the embodiments;

FIG. 8 illustrates aspects of the embodiments; and

FIG. 9 illustrates aspects of the embodiments.

### DETAILED DESCRIPTION

The figures and descriptions provided herein may have been simplified to illustrate aspects that are relevant for a clear understanding of the herein described devices, systems, and methods, while eliminating, for the purpose of clarity, other aspects that may be found in typical similar devices, systems, and methods. Those of ordinary skill may recognize that other elements and/or operations may be desirable and/or necessary to implement the devices, systems, and methods described herein. But because such elements and operations are well known in the art, and because they do not facilitate a better understanding of the present disclosure, a discussion of such elements and operations may not be provided herein. However, the present disclosure is deemed to inherently include all such elements, variations, and modifications to the described aspects that would be known to those of ordinary skill in the art.

The terminology used herein is for the purpose of describing particular example embodiments only and is not intended to be limiting. For example, as used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc., may be used herein to describe various elements, components, regions, layers and/or sections, these elements, components, regions, layers and/or sections should not be limited by these terms. These terms may be only used to distinguish one element, component, region, layer or section from another element, component, region, layer or section. That is, terms such as “first,” “second,” and other numerical terms, when used herein, do not imply a sequence or order unless clearly indicated by the context. Thus, a first element, component, region, layer or section discussed below could be termed a second element, component, region, layer or section without departing from the teachings of the exemplary embodiments.

Disclosed is a film frame and flat panel (herein referred to collectively as a “flat element”) aligner. Further, the disclosed tool may not be limited to positioning film frames. Rather, the embodiments may also position and justify FPDs or round wafers during the manufacturing processes, by way of non-limiting example.

The disclosed tool may include width guides, which open and close symmetrically about the tool centerline, and which may have a travel range of, for example, 90 mm to 400 mm. Likewise included may be longitudinal centering rollers, which open and close symmetrically about the tool centerline, and which may have a travel range of, for example, 90 mm to 400 mm.

The disclosed embodiments may also include FF V-index combs. These may provide indexable positioning, and may retract and extend on demand.

Included guide lifts may support smaller FF or wafers. Guide lifts may allow clearance to pick smaller objects with narrow end effectors which may otherwise interfere with the width guides.

Also provided in exemplary embodiments may be in-position sensing of FF or wafers. A centrally located ultrasonic sensor may check the presence of the FF on the tool. The ultrasonic sensor may detect objects regardless of their optical reflectivity.

Further included in some embodiments may be synchronously-driven axes, such as may be timing belt driven, such as by stepper motors with encoders. Also of note in exemplary embodiments may be onboard drives and controls for the synchronous axes drive.

A pneumatic version of the embodiments may be used, for example, for 150 mm, 200 mm, 300 mm FFs. Such an embodiment may include, for example, 3 position tray guides, 3 comb pin positions, and a FF justifier slide.

A first servo version of the embodiments may include servo position tray guides to handle any FF type between 150 mm-300 mm in size, by way of nonlimiting example. This version of the embodiments may include 3 pneumatic comb pin positions, and a pneumatic FF justifier slide, for example.

In a full servo-driven FF embodiment, servo position tray guides may handle any FF types of 150 mm-300 mm, by way of nonlimiting example. This embodiment may include 3 servo-comb pin positions, and a servo FF justifier slide.

Ones of the exemplary embodiments may include optional tray guide lifts. Also included may be optional wafer centering, and/or optional barcode scanning.

In semiconductor handling cells, it is often necessary to properly position film frames for inclusion in the semiconductor processes. In the typical case, the film frame positioner includes a circular metal ring onto which is placed a vinyl film to which semiconductor wafers may be bonded.

There is a significant need to better align this film frame inside the semiconductor handling cells to enable more efficient use of the film frames and semiconductor wafers in this and subsequent semiconductor processes. Likewise, a similar aligner within a handling cell is also used for display panels, and the need for improved alignment and better downstream efficiency is thus also evidenced in such a display panel aligner.

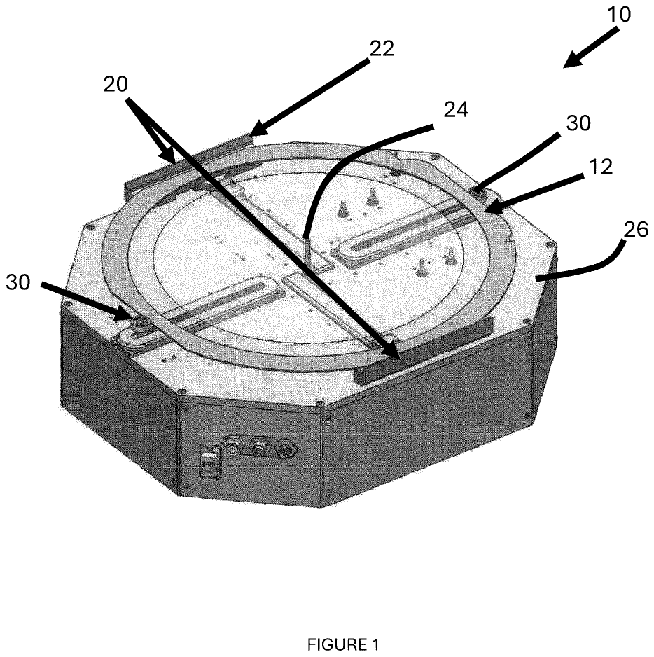

Illustrated in FIG. 1 is an aligner 10 for a film frame 12 and/or a display panel. The aligner 10 can handle multiple sizes of film frames, such as 300 mm, 200 mm, 150 mm, and smaller. That is, the embodiments provide a universal size film frame and flat panel aligner 10.

As illustrated, included in the embodiment is a width-wise axis synchronized adjustment 20, which moves so as to align the film frame along the X axis. The synchronized adjustment 20 may move terminating side guides 22, at the outermost portion of the X-axis adjustment as shown, synchronously towards or away from the center point 24 of the aligner base 26, and thus the movement range of the side guides 22 must vary over the diameter range of the film frames 12 to be aligned. In an exemplary embodiment, the adjustable range may be, by way of example, specifically between 98 millimeters and 389 millimeters for film frames having diameters between 100 millimeters and 300 millimeters. Nevertheless, the skilled artisan will appreciate that any diameter size may be used with the embodiments, so long as the side guides have a sufficient lateral travel range so as to move inward toward center or outward away from center to accommodate the film frame/wafer size in use.

Also shown are synchronized centering Y-axis rollers 30, which also may move inward toward the center 24 in the Y axis, or outward away from the center in the Y axis, so as to accommodate the diameter of a film frame 12 or a wafer. In embodiments, it may be preferable that the centering Y-axis adjustments 30 are also internally synchronized, i.e., that they move synchronously towards and away from the center point 24 of the aligner base 26. Of note, the film frame 12 illustrated in FIG. 1 is approximately 300 millimeters in diameter.

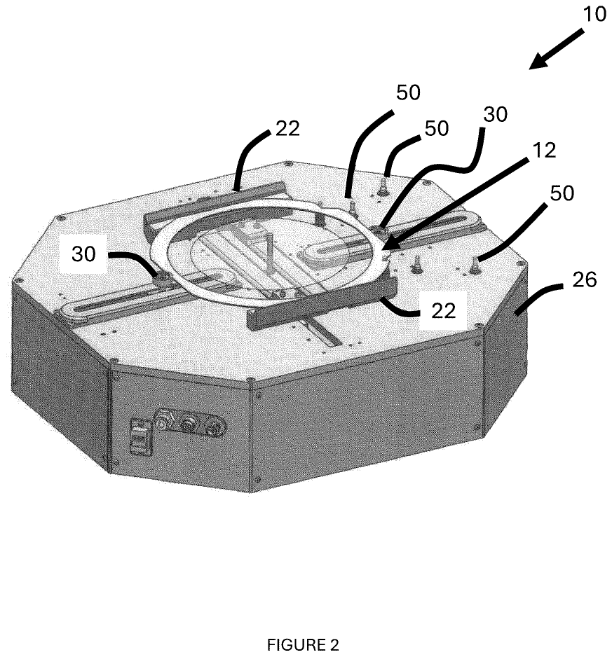

With reference now to FIG. 2, a 150 millimeter film frame 12 is shown on the aligner base 26. Of note, both the X-axis side guides 22 and the centering Y-axis rollers 30 have synchronously adjusted inward towards the center point, so as to accommodate the smaller size of the 150 millimeter diameter film frame as compared to the 300 millimeter diameter film frame illustrated in FIG. 1.

Of additional note, it may be preferable that the wafer/frame/panel size is automatically detected for an indication of the synchronous X and Y axis adjustments which are required. It may also be desirable to perform this detection via sensing that is operable regardless of the reflective qualities of the wafer/film frame/panel placed upon the aligner. Thus, by way of non-limiting example, an ultrasonic sensor may be employed to perform this size and/or location sensing.

Additionally illustrated in FIG. 2 are multiple sets of pins 50 which may engage with the registration detail on each film frame 12. As such, the pins 50 may be raised and lowered, such as pneumatically or electrically.

As will be appreciated in accordance with the description of the embodiments of FIGS. 1 and 2, a rectangular display panel, such as that used in a cell phone, may also be used with the aligner of the embodiments. For example, in such a case, the rectangular display panel may be “squared up” using the side guides and the centering Y-axis rollers, just as was performed by the side guides and centering Y-axis rollers with the circular film frames of FIGS. 1 and 2.

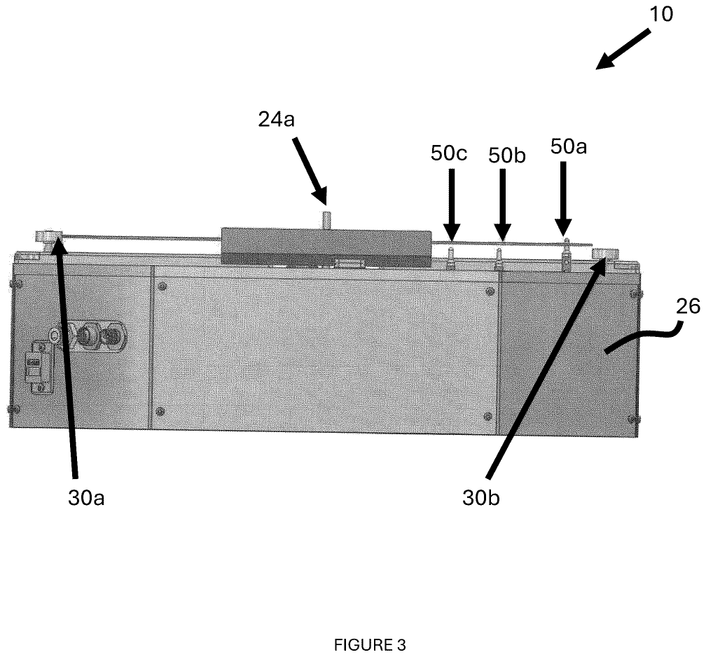

FIG. 3 illustrates a side view of an exemplary flat panel aligner 10 for film frames and/or display panels. In this illustration, staggering of the engagement pins 50 for different film frames is evident, as is the raising of the pin 50a correspondent to a 300 millimeter film frame size, and/or the lowering of the pins 50b, 50c associated with the 150 millimeter and 200 millimeter sizes. Also shown in FIG. 3 is the ultrasonic sensor 24a referenced above.

Further illustrated is the synchronous movement of the centering/justification axis rollers 30 (a and b) outwardly along the aligner base 26 to accommodate a larger film frame size. Additionally illustrated is the capability to raise (30a) or retract (30b) the justification axis rollers in order to accommodate different film frame or wafer features, and to avoid drifting of the film frame on the staging pins. In the illustration, a two position (raised or retracted) justification roller is in the raised position 30a and is engaged with the film frame on the leftmost side of the aligner base (in the illustration). In contrast, the two position justification axis roller is retracted 30b on the right hand side of the aligner (as shown), and is thus free to move underneath of the film frame if necessary for a given process.

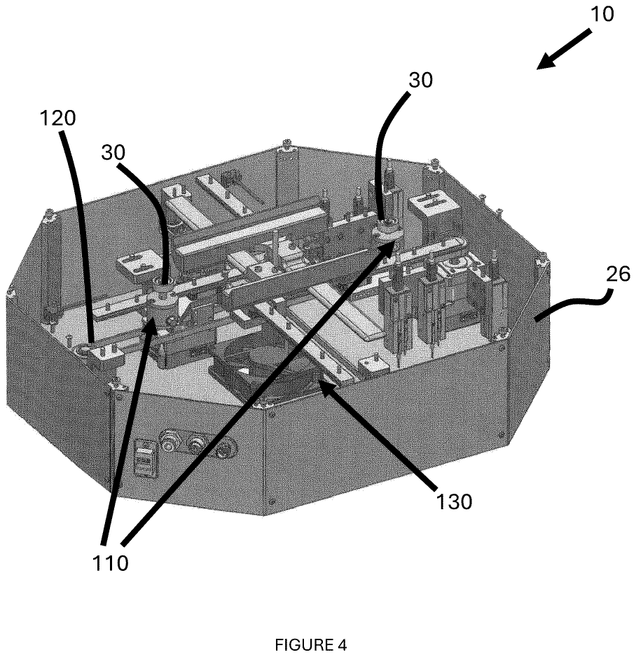

FIG. 4 illustrates aspects of the flat panel aligner 10, from a top view position with no cover on the aligner base 26. As shown, the centering/justification Y-axis rollers 30 may reside upon pneumatic cylinders 110 to enable the raising and retraction discussed herein. Further, the synchronization of the lateral movement of the centering/justification Y-axis rollers may be imparted by a belt drive 120 which may be driven by, for example, a motor, such as a servomotor.

Similarly, the X-axis side guides may be synchronously driven, such as by a belt drive driven by motor, such as a servo motor. Those skilled in the art will appreciate that a single belt and associated gearing, with one or more drive motors, may be used in the embodiments, or alternatively that each axis of adjustment (i.e., the X-axis side guides and the centering Y-axis rollers) may have its own dedicated belt and/or its own dedicated drive motor. As illustrated in FIG. 4, a synchronous drive for the X-axis side guides and the centering/justification Y-axis rollers may be staggered in elevation, such as to allow the operation of each axis of adjustment synchronously without interference with the other adjustment axis.

Also shown at the base of the aligner is one or more fans 130. The one or more fans may be used to pull particulate, such as from the drive features, out of the bottom of the aligner, so as to avoid such particulate from exiting the top part of the aligner through, for example, the movement slots for the axis adjustments. Escaping particulate may cause contamination of the film frame, wafer, or panel associated with the aligner.

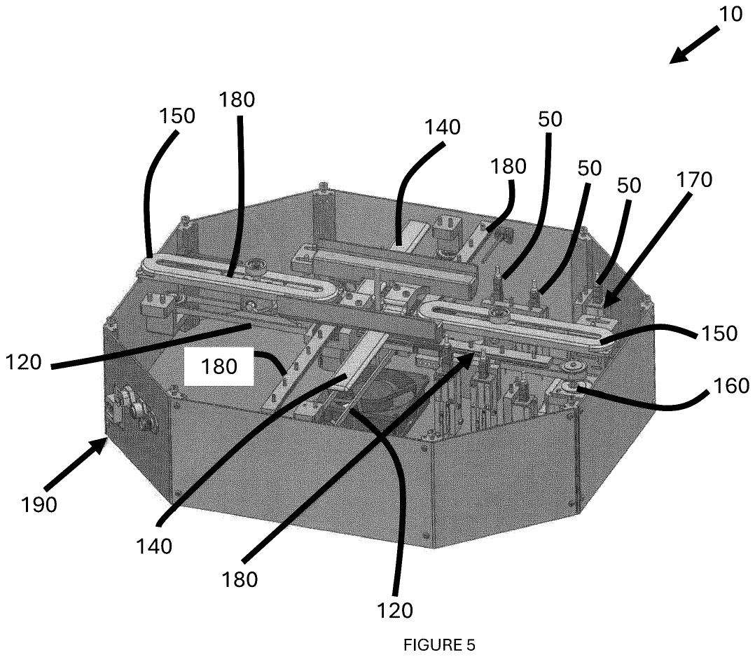

FIG. 5 is an additional illustration of a top view, without cover, of the flat panel aligner 10 disclosed herein. Shown again in this view are the differing altitudes of the drive systems for the X-axis side guides 140 and the centering Y-axis rollers 150. Also shown in this figure are dual belt drives 120 for each of the axes of adjustment, as well as at least one motor 160 associated with the belt drive(s).

Also clear from this illustration are the extendable and retractable engagement pins 50, along with the actuators 170 thereof. Also shown are four staggered linear rails 180, two for each axis of adjustment. As will be appreciated by the skilled artisan, the linear rails may be offset an order to optimize the range of adjustment provided by the aligner without enlarging the aligner. Finally, FIG. 5 illustrates both pneumatic and electrical connections 190 at the left side of the aligner (as shown).

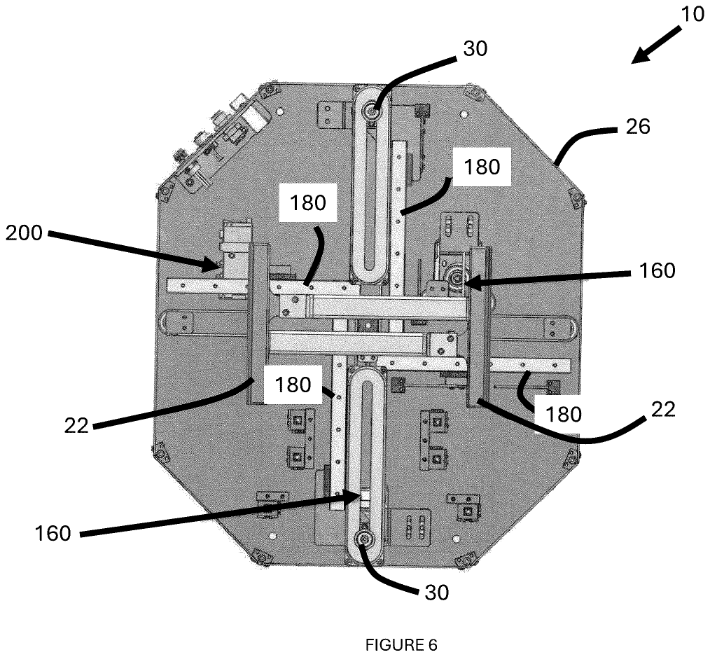

Certain of the aforementioned features are shown with greater particularity in the top view of FIG. 6 (with no cover on the aligner). Two servomotors 160 are shown in the illustration, one dedicated for each axis of adjustment. Also shown is the offset/staggered nature of the linear rails 180 adjusted by the belt drives that are driven by the servomotors 160. As will be understood, the offset nature of the linear rails may necessitate that the belt drives run in a serpentine matter, as shown, again in order to minimize the overall width of the aligner device. Needless to say, if the width of the device is minimized, the device is suitable for placement in a wider range of work cells. Finally, with respect to FIG. 6, pneumatic valves 200 are also shown, which may impart the raise and retract features of the various aspects discussed throughout.

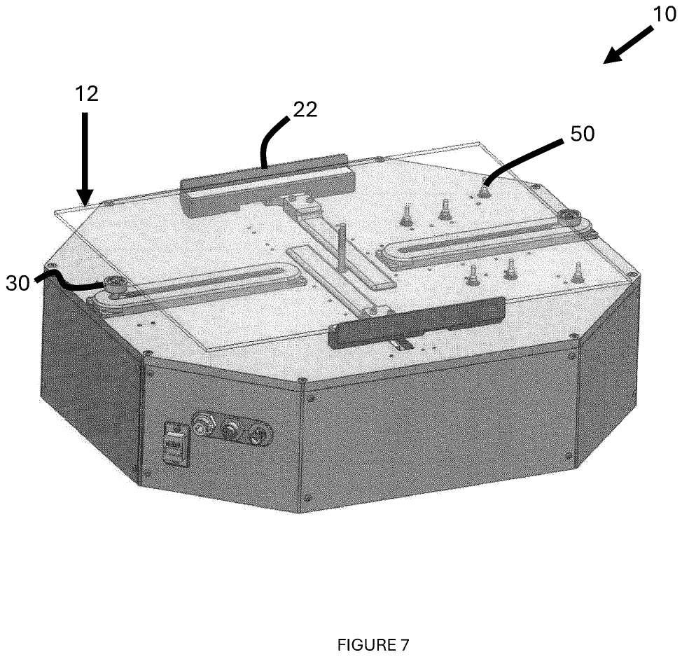

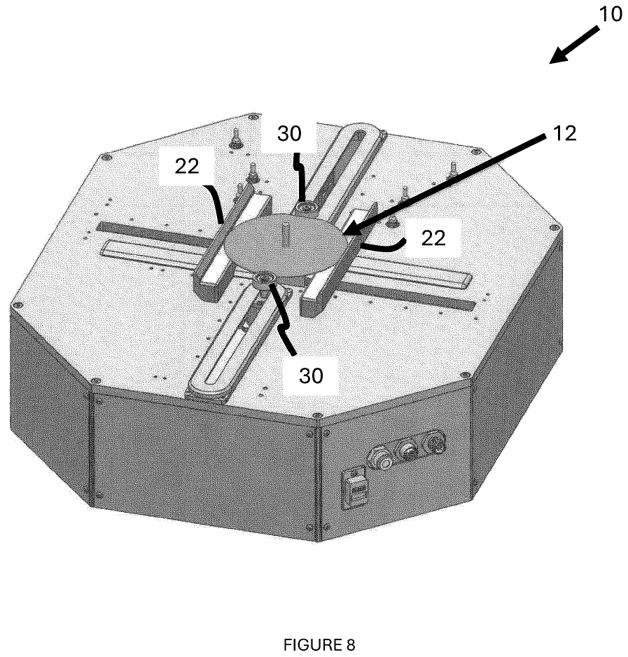

FIG. 7 illustrates the synchronized positioning of a rectangular display panel 12 on the disclosed aligner 10. The display panel shown is formed of glass, and it is held and centered by the side rails 22 and centering/justification axis rollers 30 as shown. Of further note, because there are no alignment features on the clear glass panel, engagement pins 50 are not raised so as to interact with the panel in any manner. FIG. 8 shows a 100 millimeter wafer 12 in the centered position on the disclosed aligner 10. As is evident in FIG. 8, the staggered nature of the axial adjustments (particularly in relation to the side guides 22), and a corresponding serpentine nature of the belts driving those axial adjustments, may allow for a very wide range of circular and rectangular items which may be subjected to alignment on the disclosed aligner.

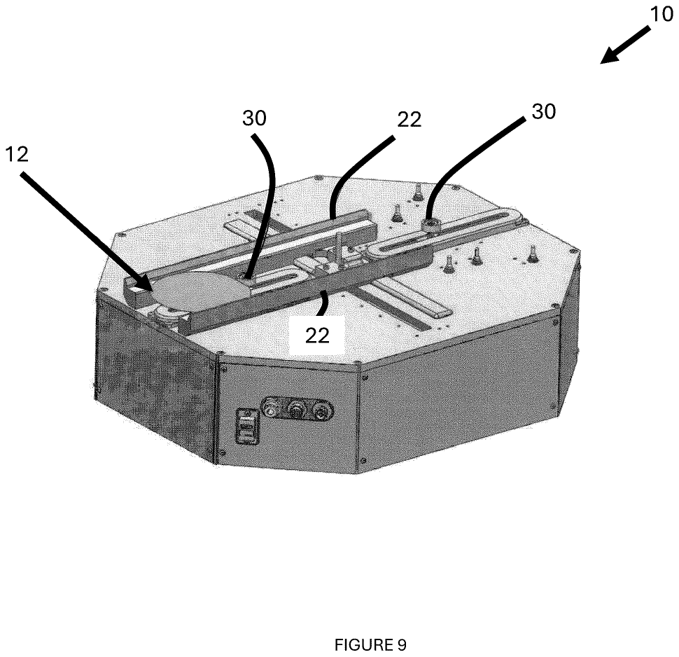

FIG. 9 illustrates an alternative embodiment in which edge access to a wafer 12, such as to provide more efficient access by certain types of end effectors, is provided using the disclosed aligner 10. As shown, the side rails 22 may again center the wafer along the X axis, but in the illustrated embodiment the wafer is placed “outside” the centering rollers 30, such that the centering roller, when synchronously moved outward, may push the wafer from its offset position outwardly towards the end of the aligner, such as to allow for grasping along the wafer's edge by an end effector.

As such, in the disclosed embodiments, an element placed upon the aligner may be positioned for movement to a subsequent chuck or operation in a semiconductor process or similar process. Of additional note, and as referenced throughout, the elements aligned by the aligner may be square or circular nature, or may be circular in nature with squared off edges, as sometimes occurs in the known art. Yet further, although the disclosure above indicates some elements may be driven pneumatically and others electrically, such as by a motor, a skilled artisan will appreciate in light of the disclosure that the reverse may also be true, i.e. those elements discussed herein as being motor driven may be pneumatically driven, and those elements herein disclosed as being pneumatically driven may be motor driven, by way of non-limiting example.

In the foregoing Detailed Description, it can be seen that various features are grouped together in a single embodiment for the purpose of clarity and brevity of the disclosure. This method of disclosure is not to be interpreted as reflecting an intention that the embodiments require more features than are expressly recited herein. Rather, the disclosure is to encompass all variations and modifications to the disclosed embodiments that would be understood to the skilled artisan in light of the disclosure.

What is claimed is:

1. A flat element aligner, comprising:
an aligner body;
two opposing slides which are along at least first parallel axes to each other, each of which terminates in a side guide distally from a center point of the aligner body, and each of which slides along a slot in an upper portion of the aligner body;
two opposing justifiers which are along at least second parallel axes to each other and which are perpendicular to the two opposing slides, each of which terminates in a roller distally from the center point of the aligner body, and each of which slides along a slot in the upper portion of the aligner body; and
at least one drive within the aligner body and below the upper portion that synchronously and symmetrically moves at least the two opposing slides closer together and farther apart, and that synchronously and symmetrically moves at least the two opposing justifiers closer together and farther apart, such that the opposing side guides and opposing rollers.

2. The flat element aligner of claim 1, wherein the flat element is a film frame.

3. The flat element aligner of claim 1, wherein the flat element is a display panel.

4. The flat element aligner of claim 1, wherein the flat element is a wafer.

5. The flat element aligner of claim 1, wherein the at least one drive is two belt drives, and wherein a first of the two belt drives is dedicated to the two opposing slides, and wherein the second of the two drives is dedicated to the two opposing justifiers.

6. The flat element aligner of claim 1, further comprising a motor within the aligner body for driving each of the at least one drives.

7. The flat element aligner of claim 6, wherein the motor is a stepper motor.

8. The flat element aligner of claim 1, wherein each of the at least one drives is a belt drive.

9. The flat element aligner of claim 1, wherein the opposing slides have a collective travel range of 90 mm to 400 mm apart.

10. The flat element aligner of claim 1, wherein the opposing justifiers have a collective travel range of 90 mm to 400 mm apart.

11. The flat element aligner of claim 1, further comprising an in-position sensor on the upper portion capable of presence-sensing the flat element.

12. The flat element aligner of claim 11, wherein the in-position sensor is an ultrasonic sensor.

13. The flat element aligner of claim 1, wherein a diameter of the flat element is one of 300 mm, 200 mm, 150 mm, or 100 mm.

14. The flat element aligner of claim 1, further comprising engagement pins for engaging with registration detail on the flat element.

15. The flat element aligner of claim 14, wherein the engagement pins each raise and lower.

16. The flat element aligner of claim 15, wherein the engagement pins operate pneumatically.

17. The flat element aligner of claim 15, wherein the engagement pins operate electrically.
